(19) United States
(12) Patent Application Publication
(10) Pub. No.: US 2026/0171979 A1
(43) Pub. Date: Jun. 18, 2026

(54) SYSTEM, METHOD AND APPARATUS FOR SUPPORTING MULTI-MODE AMPLIFIER FOR MULTIPLE WIRELESS COMMUNICATION PROTOCOLS

(71) Applicant: Silicon Laboratories Inc., Austin, TX (US)

(72) Inventors: Luigi Panseri, Bedford, MA (US); Stephan Doucet, Liffre (FR); Hervé Cam, Cernay la ville (FR); Abdulkerim Coban, Austin, TX (US); Mustafa Koroglu, Austin, TX (US); Bertrand Charles Joseph Emile Pigeard, Rennes (FR); Michael Johnson, Austin, TX (US); Dejun Wang, Austin, TX (US)

(21) Appl. No.: 18/979,732

(22) Filed: Dec. 13, 2024

(51) Int. Cl. H03F 1/56; H03F 3/24

(52) U.S. Cl. CPC H03F 1/56; H03F 3/245; H03F 2200/171; H03F 2200/387; H03F 2200/451; H03F 2200/78

(57) ABSTRACT

In one aspect, an apparatus includes: a dual-mode power amplifier to amplify a first radio frequency (RF) signal of a first wireless protocol according to a linear mode of operation, and to amplify a second RF signal of a second wireless protocol according to a non-linear mode of operation; at least one digital feedback circuit coupled to the power amplifier, the at least one digital feedback circuit to provide feedback information; and a controller to control a power level of the dual-mode power amplifier based at least in part on the feedback information.

### BACKGROUND

As the number of wireless devices ever increases, there is a great demand to provide wireless transceivers that can operate according to multiple wireless communication protocols. However, there are undesired area, power consumption and complexity costs that occur when incorporating separate circuitry within a single transceiver to support multiple protocols. And of course, there are additional component costs and similar area, power consumption and complexity concerns that inhere when providing separate transceivers for separate protocols.

### SUMMARY OF INVENTION

In one aspect, an apparatus includes: a dual-mode power amplifier to amplify a first radio frequency (RF) signal of a first wireless protocol according to a linear mode of operation, and to amplify a second RF signal of a second wireless protocol according to a non-linear mode of operation; at least one digital feedback circuit coupled to the power amplifier, the at least one digital feedback circuit to provide feedback information; and a controller to control a power level of the dual-mode power amplifier based at least in part on the feedback information.

In an implementation, the at least one digital feedback circuit includes an envelope detector comprises: a comparator to compare a measure of the first RF signal to a reference value and output a digital value based on the comparison; and a digital filter coupled to the comparator, the digital filter to output, based at least in part on the digital value, the feedback information comprising an envelope amplitude square value of the first RF signal. In this or another implementation, the at least one digital feedback circuit includes a current detector comprising: a comparator to compare a first value representative of a current output by a voltage regulator coupled to the dual-mode power amplifier to a reference value and output a digital value based on the comparison; and a digital filter coupled to the comparator, the digital filter to output, based at least in part on the digital value, the feedback information comprising the current output by the voltage regulator.

In an implementation, the controller is to determine a correction value for the dual-mode power amplifier, based at least in part on the feedback information obtained during a preamble portion of a first packet and at least one stored calibration value. The controller is to: calculate a gain swing based on a voltage value of the feedback information and a first calibration value from a non-volatile memory; calculate a difference between a current value of the feedback information and a second calibration value from the non-volatile memory; determine a load gain based at least in part on the difference; and determine the correction value based on the gain swing and the load gain.

In one or more implementations, the controller is to apply the correction value for a second packet following the first packet. The controller is to apply the correction value for the second packet via an update to a level of digital data of the second packet. The dual-mode power amplifier may include a plurality of slices, where a portion of the plurality of slices are to be re-used in the linear mode of operation and the non-linear mode of operation. The controller, based at least in part on the feedback information, is to update a number of active slices of the plurality of slices.

In yet another aspect, a method includes: amplifying, in a power amplifier of a wireless device operating in a linear mode, a first RF signal of a first wireless protocol; amplifying, in the power amplifier operating in a non-linear mode, a second RF signal of a second wireless protocol; and controlling a programmable impedance circuit coupled to an output of the power amplifier based at least in part on a power level of the power amplifier.

In an implementation, the method further includes: during a preamble portion of a first packet, digitally measuring a voltage at the output of the power amplifier via a first digital detector; and during the preamble portion of the first packet, digitally measuring a current output by a voltage regulator that supplies an operating voltage to the power amplifier via a second digital detector. The method may further include: determining a gain calibration for the power amplifier based at least in part on the voltage, the current, and one or more calibration values stored in a non-volatile memory; and applying the gain calibration to the power amplifier during a second packet.

In an implementation, applying the gain calibration comprises one or more of: updating a level of digital data of the second packet; controlling the programmable impedance circuit; and/or when the power amplifier comprises a plurality of slices, updating a number of the plurality of slices to be enabled.

In an implementation, when the power amplifier comprises a plurality of slices, the method further includes: amplifying, in a first number of slices of the plurality of slices of the power amplifier operating in the non-linear mode, the second RF signal of the second wireless protocol; and amplifying, in a second number of slices of the plurality of slices of the power amplifier operating in the linear mode, the first RF signal of the first wireless protocol, at least some of the first number of slices included in the second number of slices. The method may also include: controlling the programmable impedance circuit to have a first impedance level when amplifying the first RF signal; and controlling the programmable impedance circuit to have a second impedance level when amplifying the second RF signal.

In yet another aspect, a system includes: an antenna to transmit and receive RF signals; and a multi-protocol transceiver coupled to the antenna. The multi-protocol transceiver includes: a dual-mode power amplifier to amplify a first RF signal of a first wireless protocol according to a linear mode of operation, and to amplify a second RF signal of a second wireless protocol according to a non-linear mode of operation; an impedance transformation circuit coupled to an output of the dual-mode power amplifier; at least one digital feedback detector coupled to the dual-mode power amplifier, the at least one digital feedback detector to provide feedback information; and a controller to control an impedance of the impedance transformation circuit based at least in part on the feedback information.

In an implementation, the system further includes a non-volatile storage to store compensation data, the compensation data comprising a first compensation value associated with an output voltage of the dual-mode power amplifier and a second compensation value associated with a load current of the dual-mode power amplifier. The controller may be configured to control the impedance of the impedance transformation circuit further based on at least one of the first compensation value or the second compensation value.

### BRIEF DESCRIPTION OF THE DRAWINGS

FIG. 1 is a high level block diagram of a multi-mode wireless transmitter in accordance with an embodiment.

FIG. 2 is a more detailed illustration of a transmit path in accordance with an embodiment.

FIG. 3 is a schematic diagram of a circuit including a digital-to-analog converter (DAC) in accordance with an embodiment.

FIG. 4 is a schematic diagram of further aspects of a transmit path architecture in accordance with an embodiment.

FIG. 5 is a schematic diagram of additional aspects of a transmit path architecture in accordance with an embodiment.

FIG. 6 is a schematic diagram of a plurality of driver slices of a dual-mode power amplifier in accordance with an embodiment.

FIG. 7A is a schematic diagram of a digital envelope detector in accordance with an embodiment.

FIG. 7B is a schematic diagram of a digital envelope detector in accordance with another embodiment.

FIG. 8 is a schematic diagram of a digital current detector in accordance with an embodiment.

FIG. 9 is a flow diagram of a method in accordance with an embodiment.

FIG. 10 is a block diagram of a representative integrated circuit in accordance with an embodiment.

FIG. 11 is a high level diagram of a network in accordance with an embodiment.

### DETAILED DESCRIPTION

In various embodiments, a wireless transmitter architecture is provided that provides certain transmit circuitry that can operate in multiple modes. That is, this circuitry, which as will be described herein includes a power amplifier (PA) and impedance transformer circuitry, can be dynamically controlled to support multiple communication protocols that have different requirements. For example, a first wireless communication protocol may call for use of a linear transmitter (to meet linearity requirements), and a second wireless communication protocol may call for use of a non-linear transmitter (for better efficiency).

As non-exhaustive illustrations, in one implementation this transmit architecture may share circuitry for use with Bluetooth Classic (BTC) and Bluetooth Low Energy (BLE) protocols. The transmit architecture is configured to operate at different transmit saturated power levels for these different protocols. In embodiments, the multi-mode transmitter can be implemented with reduced chip area and optimized efficiency for each protocol and power level, as will be described herein.

In one or more embodiments, a transmitter can support multiple modes of operation (such as different communication protocols), and optimize efficiency across different power levels. To effect such operation, a dual-mode power amplifier (PA) can be implemented to transmit constant envelope modulated signal when configured as a non-linear PA, and transmit non-constant envelope modulated signals when configured as a linear PA. In turn, an output of the PA couples to a programmable shunt inductor, which optimizes the PA efficiency at different power levels. As will be described, additional transmitter circuitry can aid in reduced size, including a baseband R-2R digital-to-analog converter (DAC), sharing of the PA between multiple protocols, and avoiding use of an output balun.

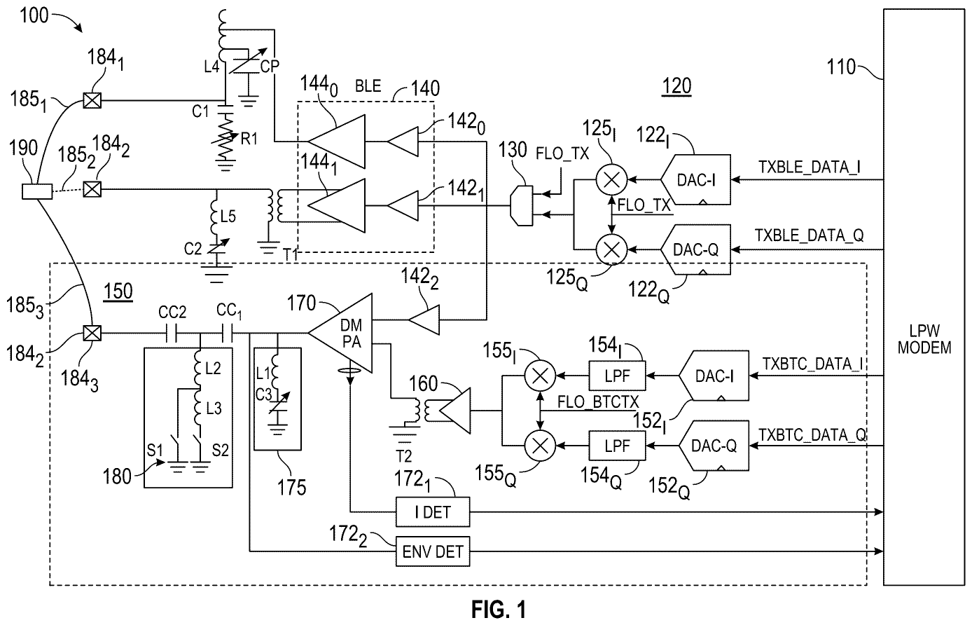

Referring now to FIG. 1, shown is a high level block diagram of a multi-mode wireless transmitter in accordance with an embodiment. In the high level of FIG. 1, apparatus 100 is shown including only certain circuitry. However understand that in different implementations, apparatus 100 may be a multi-protocol transceiver, such as may be implemented on one or more semiconductor die of a single integrated circuit (IC).

In other implementations, apparatus 100 may be a given wireless device incorporating such a transceiver. For example, in different use cases, apparatus 100 may be an Internet of Things (IoT) device, smartphone, tablet computer, access point, wireless router, gateway device, among many other such wireless devices.

In any case, in the high level view shown in FIG. 1, apparatus 100 includes a low power wireless (LPW) modem 110, which may perform various PHY operations including coding and decoding operations for multiple wireless protocols, both in transmit and receive directions. Understand that for ease of discussion and illustration, only transmit path circuitry is shown in FIG. 1. However, in typical use cases such as for a multi-protocol transceiver, receiver path circuitry also is present.

As illustrated, separate transmit paths 120 and 150 are present. In the embodiment of FIG. 1, transmit path 120 is implemented as a BLE transmit path, while transmit path 150 is implemented as a BTC transmit path. While in the embodiment of FIG. 1, a dual-mode transmitter is shown for communicating according to BLE and BTC communication protocols, embodiments are not limited in this regard. In other implementations, the transmit paths may be used for other wireless protocols, such as combinations of a Bluetooth protocol, Wi-Fi, Wi-SUN, among others. For example, the dual-mode transmitter may be configured as a linear transmitter to transmit, in addition to BTC signals, Wi-Fi signals or other non-constant envelope signals, and may be configured as a non-linear transmitter to transmit, in addition to BLE signals, Zigbee, Thread or other constant envelope signals.

Starting first with transmit path 120, baseband signals output from modem 110 are provided as a complex data stream formed of I and Q data, which is converted to analog form in corresponding digital-to-analog converters (DAC) 122_{I,Q}. In turn, the baseband signals are upconverted to a given radio frequency (RF) via a complex mixer 125_{I,Q}. As shown, mixer 125 upconverts the signals using a transmit local oscillator frequency clock signal (Flotx).

Still referring to FIG. 1, the resulting RF signals pass through a multiplexer (illustrated as a logic circuit 130), which as shown can be controlled via this LO clock signal. In turn, the RF signal is provided to BLE transmit circuitry 140 which, as shown, includes pre-drivers 142_{0,1} and drivers, also referred to herein as PAs 144_{0,1}. These different pre-drivers and PAs may be configured to operate at different power levels. As an example, PA 144₀ may be implemented as a 0 dBm PA, and PA 144₁ implemented as a 20 dBm PA. Depending upon incorporation into a given device, it is possible that only one of these PAs is active, and only such active PA is coupled to an output pad 190 via a given one of bond wires 185₁, 185₂. More specifically, in the illustration of FIG. 1, bond wire 185₂ is shown in dashed line, indicating that a bond wire is not present here, such that PA 144₁ can be configured to be inactive.

Note further that the BLE RF signal also is provided to another BLE pre-driver 142₂, which as shown, is included within transmit path 150. However, note that this location of pre-driver 142₂ is not important, and depending upon a particular device's layout, this pre-driver can equally be located within transmit path 120.

As shown in FIG. 1, an RF signal output from PA 144₀ couples through and output inductor L2 to an output pad 184₁. Also note the presence of a programmable capacitor CP coupled to inductor L4 and a programmable filter formed of serially coupled capacitor C1 and resistor R1. An RF signal output from PA 144₁ is transformed to a single-ended signal via a balun formed of a transformer T1. Filtering circuitry also couples to output pad 184₂, namely serially-coupled inductor L5 and capacitor C2.

At a high level, transmit path 150 may include similar circuitry discussed above with regard to transmit path 110, such as DACs 152_{I,Q} and mixer 155_{I,Q}. As shown, low pass filters (LPFs) 154_{I,Q} couple between DACs 152 and mixer 155_{I,Q}.

Note also that variations and additional transmit circuitry are present in transmit path 150. For example, mixers 155_{I,Q} couple to a BTC pre-driver 160, which outputs a differential signal that, in turn, is transformed back to single-ended via a transformer T2. Next, a dual-mode (DM) PA 170 is coupled to receive both BLE and BTC RF signals, with a given signal stream active at a given time, as will be discussed further herein.

Also, while dual-mode PA 170 is shown at a high level in FIG. 1, understand that in practical implementations it may be formed of a plurality of units or slices that can be individually controlled to output a transmit RF signal to be at a desired power level. As shown, dual-mode PA 170 is a single-ended PA that outputs a single-ended amplified RF signal.

At an output of PA 170, additional circuitry is present, namely, a harmonic trap circuit 175, which may trap certain harmonics (e.g., H3 harmonics for BLE mode) and a switchable impedance transformer 180, which may be dynamically controlled depending upon desired transmit power level. In an embodiment, harmonic trap circuit 175 includes a series-coupled inductor L1 and programmable capacitor C3, which can be controllers to cause H3 harmonics, which may fall in a GPS band, to be reduced or eliminated. As further shown, coupling capacitor CC_{1,2}, act as DC blocks and pass AC currents to an output pin 184₃.

Depending on an active wireless protocol, dual-mode PA 170 can amplify and output phase modulated signals and amplitude modulation (AM)-PM modulated signals with reduced losses and area consumption. In addition, impedance transformer 180, which may be implemented as a programmable shunt inductor, can be dynamically controlled to realize different PA impedances. In the embodiment of FIG. 1, switchable impedance transformer 180 includes serially coupled inductors L2, L3 that can be programmably switched to shunt via switches S1, S2, which may be implemented as metal oxide semiconductor field effect transistors (MOSFETs). As will be described herein, impedance transformer 180 can be controlled to provide suitable power control and impedance matching for the different modes of DM PA 170. In a particular implementation, impedance transformer 180 can be dynamically controlled to provide an impedance of between approximately 5-20 ohms. In this way, efficiency of PA 170 can be optimized for different power levels.

Finally, as also shown in FIG. 1, one or more feedback detectors 172 may be coupled to the output of PA 170 to monitor current and/or envelope information and provide this feedback information to modem 110. As will be described further below, in certain embodiments these detectors can be implemented digitally. In turn, a controller (included in or coupled to modem 110, but not shown for ease of illustration) can determine appropriate power levels for the pre-drivers 142, and/or PAs 144, 170. Although shown at this high level in the embodiment of FIG. 1, many variations and alternatives are possible.

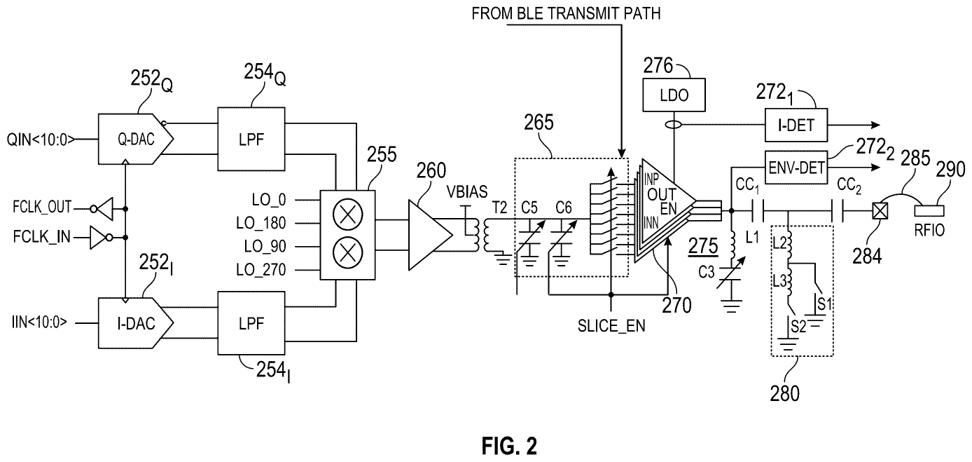

Referring now to FIG. 2, shown is a more detailed illustration of a transmit path in accordance with an embodiment. More specifically, as shown in FIG. 2, in the high level view shown in FIG. 2, transmitter 200 is implemented as a BTC transmit path. Of course, as discussed above, this same transmit path can be used with other wireless communication protocols. At a high level, similar circuitry shown in transmit path 150 of FIG. 1 is illustrated in FIG. 2, and thus the above discussion applies equally here (note that these same components are shown using the same numerals as FIG. 1, albeit of the “200” series).

In an embodiment, DACs 252 may be implemented as 11-bit DACs, to receive incoming 11-bit data in the I and Q paths. As will be described further below, DACs 252 may be implemented as segmented R-2R DACs. This arrangement of DACs 252 reduces considerably chip area (compared to same resolution current steering topologies). In turn, the resulting analog signals are provided to corresponding to LPFs 254_{I,Q}. In an embodiment, LPFs 254 may be implemented as second-order Rauch, Butterworth magnitude response filters.

As shown, the quadrature signals are provided to a passive mixer 255_{I,Q}. Mixers 255 may be implemented differentially with bootstrap NMOS switches. In various implementations, mixers 255 may be implemented as voltage mode passive mixers, which reduces area and current consumption (as compared to a Gilbert-cell based mixer). In turn, the resulting upconverted signals, now at RF, are provided to a pre-driver 260. In an embodiment, pre-driver 260 may be implemented as a complementary class AB pre-driver.

The resulting driven signals are provided to a transformer T2, which as shown on the secondary, acts as a balun to pass single-ended signals to a switch array 265, which as discussed below, may be implemented with NMOS switches.

Note further that frequency tuning may be performed via corresponding shunt-coupled capacitor C5, which may be implemented as a programmable capacitor. In addition, another shunt-coupled capacitor C6, also implemented as a programmable capacitor, is configured to provide loading capacitance compensation, which may be based on an active size of a PA 270, implemented as a dual-mode driver.

Still with reference to FIG. 2, incoming signals from a BLE transmit path, namely BLE RF signals, also are provided to dual-mode driver 270, e.g., via another pre-driver (not shown for ease of illustration in FIG. 2). Based on an incoming enable signal, a selected number of the switches of switch array 265 and corresponding slices of driver 270 (and elements of programmable capacitor C6) may be enabled. The enabled slices operate to amplify the corresponding RF signals, which are output via an output pad 284 to a RF input/output (RFIO) pad 290, via bond wire 285.

As further shown, harmonic trap circuit 275 is implemented with a series coupling of an inductor L1 and capacitor C3. In BTC mode, capacitor C3 is shunted to suppress harmonics, namely, an H3 harmonic. In turn, impedance transformer 280 may be programmably controlled based upon desired transmit power level. For example, when a desired saturation power level (Psat) is at 10 dBm, the inductors of impedance transformer 280 may be disabled. Continuing with this example, when a desired Psat is at 13 dBm, a large value of inductors is realized by shunting inductor L3 of impedance transformer 280. And further continuing this example, when a desired Psat is at 16 dBm, inductor L2 of impedance transformer 280 may be shunted. Of course, other control schemes are possible in other examples.

In one or more embodiments, with this programmable control via impedance transformer 280, impedance (namely output impedance at an output node of driver 270) can be dynamically controlled to be between, e.g., approximately 16 ohms and approximately 5 ohms.

As further shown, a supply voltage is provided to PA 270 via a low drop out (LDO) voltage regulator 276. An LDO current can be measured via a current detector 272₁, which as described further below, can be implemented as a digital detector. Similarly, an envelope detector 272₂ may be implemented as a digital detector to measure a voltage level of the output RF signal, as further described below. Although shown at this high level in the embodiment of FIG. 2, many variations and alternatives are possible.

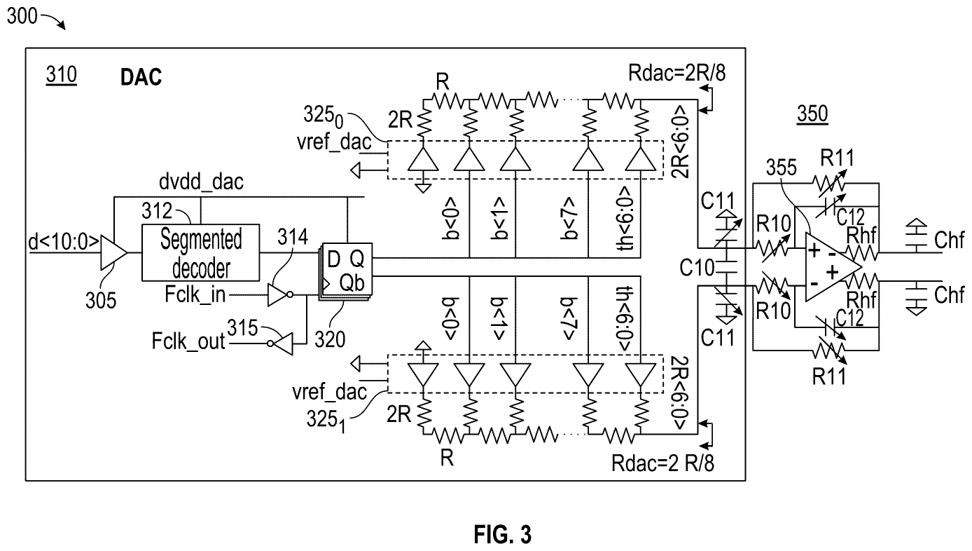

Referring now to FIG. 3, shown is a schematic diagram of a circuit including a digital-to-analog converter (DAC) in accordance with an embodiment. As shown in FIG. 3, circuit 300, which may be part of a transmit path, includes a DAC 310. As shown in FIG. 3, DAC 310 is implemented as a segmented R-2R DAC having a current mode design. As shown, an incoming digital word (d[10:0]) is provided to a segmented decoder 312 via a buffer 305. Decoder 312 drives a set of D-type flip-flops 320, which as shown are clocked via a clock signal (Fclkin) , received via an inverter 314. As further shown, this clock signal is further output as an output clock signal (Fclkout) via another inverter 315.

Still referring to FIG. 3, the outputs of flip-flops 320 drive a set of legs of corresponding resistor ladders formed of series-coupled 2R resistors and parallel-coupled R resistors. As seen, the individual bits of the bitstream couple to the resistor ladders via sets of buffers 325_{0,1}. With a segmented design, 8 bits feed directly through these buffers, while 3 bits are segmented, e.g., with thermometer weighting.

In embodiments, the segmentation may be a function of DAC output resistance, with more segmentation leading to a lower settling time, a lower resistance, higher filter capacitance and higher op-amp sink/source current capability. Note that a reference voltage (vref_DAC) may be generated by a reference voltage generator, e.g., a LDO regulator, which may be provided on a per channel basis (namely, per I and Q DACs). In contrast, an LDO that provides a supply voltage for digital circuitry (dvdd_dac) may be shared by the I and Q DACs.

Still referring to FIG. 3, the analog output of DAC 310 is provided to filter 350, which may be implemented as a second order Butterworth Rauch architecture filter, via common mode paths coupled together via a capacitor C10. As also shown, programmable capacitors C11 couple to input nodes of filter 350. In turn, the analog signals are input to an op-amp 355 through programmable resistors R10. Op-amp 355 outputs a filtered signal through a corresponding RC filter formed of resistors Rhf and capacitors Chf. In an embodiment, an output filter formed of capacitors CHF and resistors RHF implements a low pass filter at 800 MHz, to prevent filter noise from leaking into a GPS band.

As further shown, filter 350 implements a feedback loop having programmable feedback resistors R11 and programmable feedback capacitors C12. This feedback loop enables the common mode to remain centered. Note that the input signal to op-amp 355 is at a fixed input common mode. Capacitor C10 may improve out-of-band noise. Although not shown in FIG. 3, understand that the analog output signals are provided to a mixer for upconversion to RF levels.

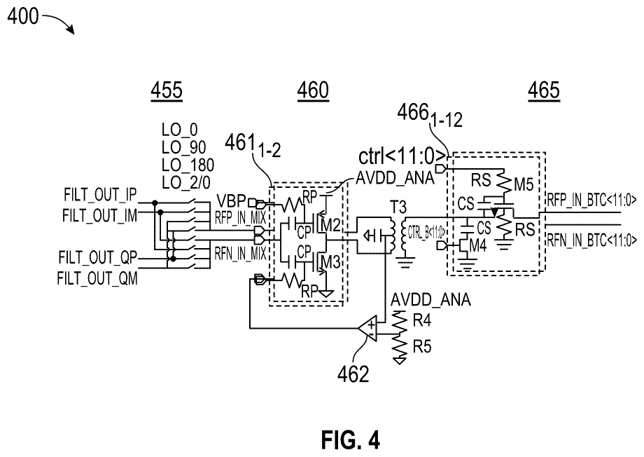

Referring now to FIG. 4, shown is a schematic diagram of further aspects of a transmit path architecture in accordance with an embodiment. As shown in FIG. 4, circuit 400 includes a mixer 455, which upconverts the analog signals to RF levels. These RF signals in turn are provided to a pre-driver 460, which in turn passes outputs to a switch array 465.

Starting first with mixer 455, which is implemented as a passive mixer, incoming filtered signals (FILT_OUT_M, P) couple to corresponding source terminals of metal oxide semiconductor field effect transistors (MOSFETs) M1, which as shown are implemented as N-channel MOSFETs (NMOS). The filtered signal also couples to a gate terminal of NMOS M1 at a midpoint node between a series-coupled resistor RM and capacitor CM. As seen, capacitor CM couples to a buffer 452 (powered by a LDO 415) and which outputs clock signals to perform the upconversion to RF level. Specifically, mixer 455 is implemented to receive, via buffer 452, 25% local oscillator (LO) clock signal phases, which may be received from a clock generator and are used to control switching of the given phases to result in an RF output signal (RF_OUT_P, M). In the embodiment of FIG. 4, mixer 455 is implemented as a fully differential passive mixer having 25% LO stages to drive pre-driver 460. By providing a passive mixer, current consumption may be reduced.

Note that the specific implementation shown on the lefthand side of FIG. 4 is illustrated as a simple set of switches in the middle of FIG. 4 to provide RF input signals to a pre-driver 460. As shown, pre-driver 460 may be implemented with two units 461₁₋₂. As illustrated, each unit receives a corresponding RF signal, which is provided through capacitors CP to gate terminals of a pair of MOSFETS M2, M3, namely, a P-channel MOSFET (PMOS) M2 and NMOS M3. The commonly coupled drain terminals of MOSFETs M2, M3 in turn drive a transformer T3, implemented as a balun to provide a single-ended signal to corresponding stages of a switch array 465.

In the embodiment of FIG. 4, pre-driver 460 may be implemented as a complementary class-AB pre-driver. With this design, a double transconductance may be realized for a given quiescent current. Still further, pre-driver 460 may reduce/cancel second harmonic distortion and act to filter baseband, mixer and pre-driver out-of-band noise.

As further illustrated, a feedback loop is provided from a center tap of the primary side of transformer T3, which couples to a first input of an op-amp 462, having a second input coupled to receive a voltage from a resistor ladder formed of resistors R4, R5. As shown, op-amp 462 outputs a feedback voltage provided to resistors RP of pre-driver 460 to keep common mode centered.

Switch array 465 may be implemented to isolate driver inputs, while operating with low power and low noise linearity. This switch circuitry may be provided in various embodiments, to decouple driven RF signals from pre-driver circuitry to a dual-mode PA when this signal path (e.g., as used for BTC communications) is inactive. Such switch circuitry may be used to decouple pre-driver circuitry such as pre-driver 460, since presence of transformer T3 prevents isolation between inputs.

As shown, switch array 465 may be implemented with a set of individual switch units 466₁₋₁₂, each of which is controlled by a digital control signal (ctrl[11:0]) and (CTRL_b [11:0]). As shown, each switch unit 466 is implemented with a shunt NMOS M4 and a series NMOS M5, and corresponding capacitors CS and resistors RS. When a given switch unit 466 is active via an active CTRL control signal (and an inactive CTRL_b control signal) and receives an input from pre-driver 460 via transformer T3, a single-ended RF signal couples via NMOS M5, and is output as RFN_IN_BTC (and when a given switch unit 466 is active and receives an input from pre-driver 460 via transformer T3, a single-ended RF signal couples via NMOS M5, and is output as RFP_IN_BTC). NMOS M4 may be controlled to provide automatic tuning of transformer T3 along with output stage slices. Note that a corresponding RF signal is output via additional switch units 466. Understand that the outputs of switch array 465 are provided as inputs to one or more slices of a dual-mode PA as described herein.

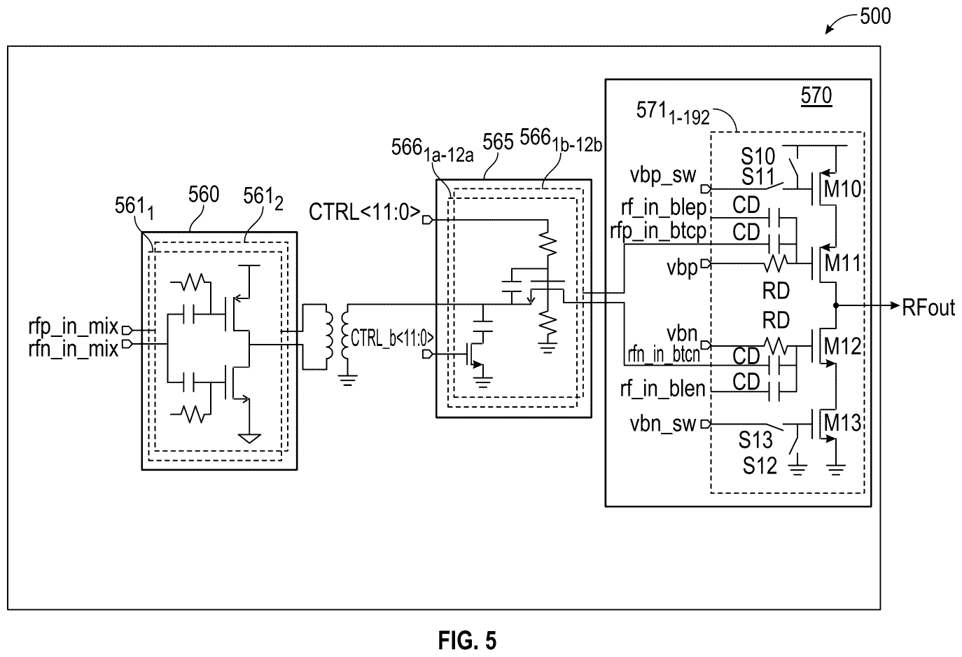

Referring now to FIG. 5, shown is a schematic diagram of additional aspects of a transmit path architecture in accordance with an embodiment. As shown in FIG. 5, circuit 500 includes a pre-driver 560, which outputs driven RF signals to a switch array 565, which switchably passes the RF signals to a dual-mode PA 570. As illustrated, in circuit 500 pre-driver 560 (formed of pre-driver stages 561_{1,2} and switch array 565 (formed of switch units 566_{1a-12a/1b-12b}), may be configured as described above in FIG. 4, and thus are not further discussed here (understand while the specific enumerations shown in FIG. 4 are not included for ease of illustration in FIG. 5, the same components are present).

In FIG. 5, a detailed implementation of a single slice of dual-mode PA 570 is illustrated. More specifically, driver 570, namely the dual-mode PA, is implemented with a plurality of slices 571₁₋₁₉₂. Although shown with this specific number of slices in the embodiment of FIG. 5, more or fewer slices may be present. As seen, slice 571 receives incoming RF signals of both BTC and BLE paths (namely RF(P, N)_IN_BTC and RF_IN_BLE). These RF signals couple through capacitors CD to corresponding gate terminals of MOSFETs, namely, PMOS device M10 and NMOS device M12. As shown, a given slice may be controllably switched in via a set of switches S10-S13 to control MOSFETs M10, M13, which when enabled cause the slice to be enabled (and vice versa). Additionally, bias signals VBP and VBN may be driven by separate bias blocks to appropriately bias the MOSFETs depending upon mode of operation.

Note that with this arrangement, each slice 571 may be re-used for both BTC and BLE modes, realizing reduced circuit size. When a given slice 571 is enabled, it outputs an amplified RF signal, RFout, which is combined with similar RF outputs of other slices to form an amplified RF output signal.

Note that in some implementations, only some number of slices are used for BLE mode, while potentially all slices can be used for BTC mode, depending upon power requirements. As one particular example, half of the slices may be available for BLE mode, with all slices available for BTC mode.

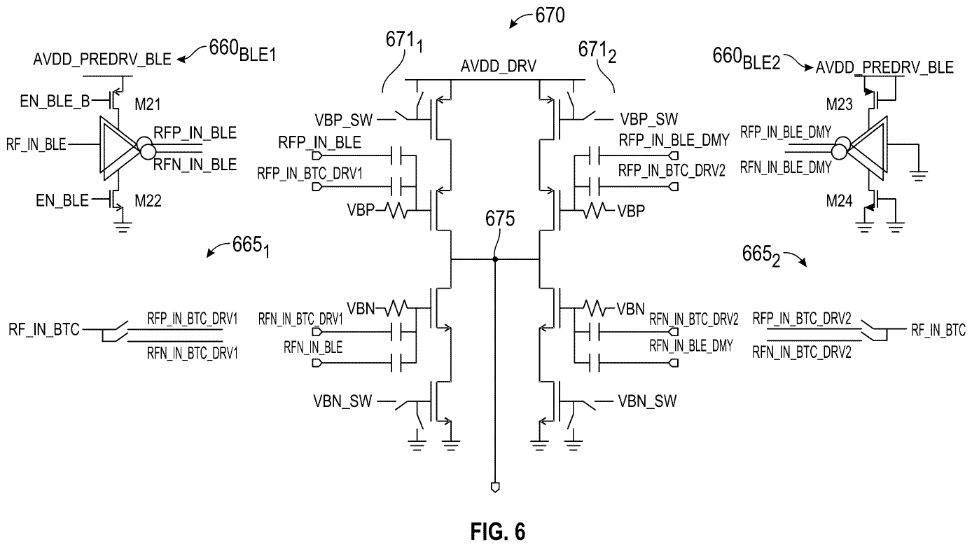

Referring now to FIG. 6, shown is a schematic diagram of multiple driver slices 671_{1,2} of a dual-mode PA 670 in accordance with an embodiment. In this implementation, slice 671₁ may be active in both BTC and BLE modes, while slice 671₂ is only active in BTC mode. This can be seen, as the BLE inputs provided to slice 671₂ are from a dummy pre-driver 660_{BLE2.} Note that this pre-driver is controlled to remain in tri-state via the fixed pull up of PMOS M23 and pull down of M24. In contrast, BLE pre-driver 660_{BLE1} may be dynamically controlled to pass a BLE RF signal for input into slice 671₁, when enabled via appropriate enabled signals coupled to gate terminals of MOSFETs M21, M22. And when BLE communication is not active, pre-driver 660_{BLE1} can be placed into a tri-state to present a high impedance to PA 670.

As further shown in FIG. 6, switching circuitry 665_{1,2} (which may take the form of switch array 565 of FIG. 5) is provided to be controlled to pass BTC RF signals to slices 671_{1,2}.

With further reference to dual-mode driver 670, the amplified RF outputs of slices 671_{1,2} couple together via an output node 675 (which may also couple to the outputs of all other enabled slices of driver 670. Although shown at this high level in the embodiment of FIG. 6, many variations and alternatives are possible.

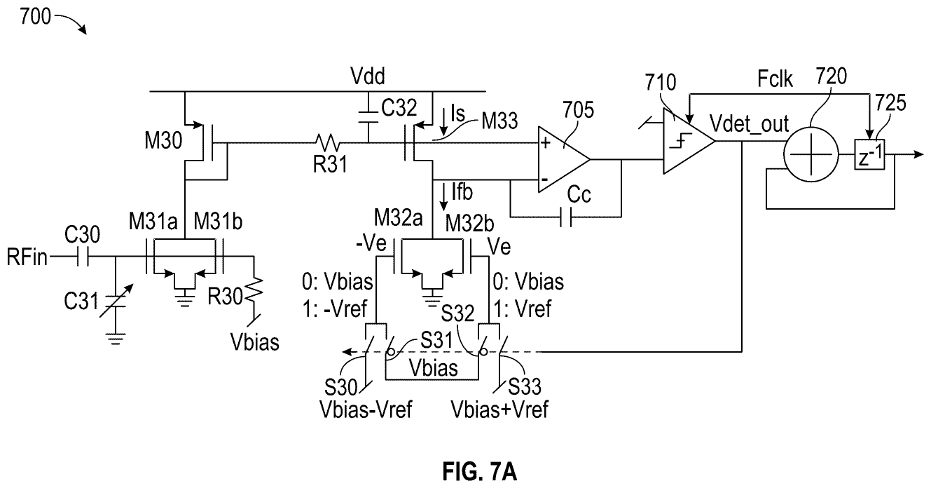

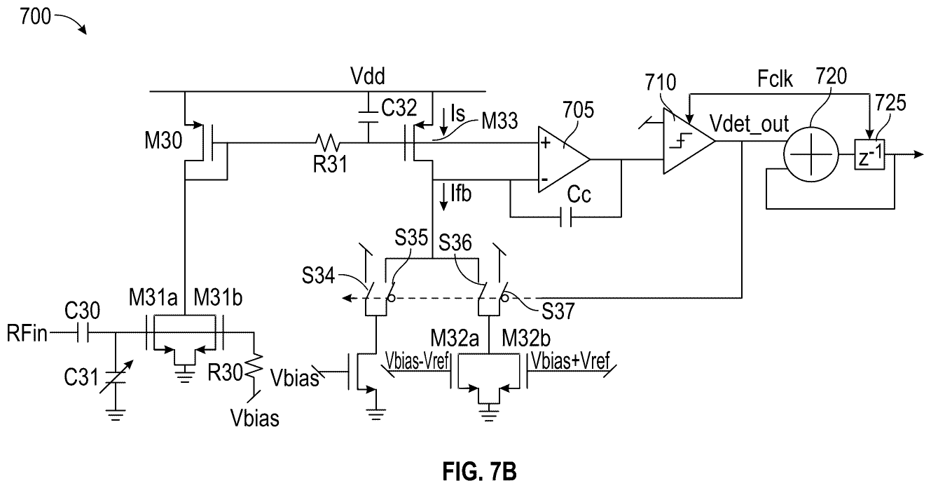

As discussed above, feedback detectors coupled to an output of a dual-mode PA can be implemented as digital detectors to ease implementation. Referring now to FIG. 7A, shown is a schematic diagram of a digital envelope detector in accordance with an embodiment. As shown in FIG. 7A, detector 700 is coupled to receive an RF signal (RFin), which may be the RF signal output from the PA (e.g, an output voltage at drain terminals of the output MOSFETs of the enabled slices of the PA).

As shown, this RF input couples through a capacitor C30 to gate terminals of a pair of commonly coupled NMOS devices M31a, M31b. NMOS devices M31 have commonly coupled source terminals coupled to a reference voltage node and commonly coupled drain terminals that couple to a PMOS device M30, more specifically, to gate and source terminals of diode-connected PMOS device M30. In turn, PMOS device M30 is coupled via a resistor R31 to another PMOS device M33 via commonly coupled gate terminals. PMOS device M33 has a drain terminal coupled to a feedback path.

As further shown, the commonly coupled drain and gate terminals of PMOS M33 couple to a first input of an op-amp 705, which compares this signal representative of the RF signal current (Is) to a feedback signal (Ifb) received via a feedback path coupled to an output of a level detector 710. Op-amp 705 is configured to output a comparison signal based on the incoming signals. This comparison signal is provided to level detector 710, which digitizes the input to a digital value (0 or 1, depending on the comparison result), and which provides a pulse density.

Still referring to FIG. 7A, the digital value representative of the detected output voltage is provided to a digital filter formed of an accumulator 720 and a delay element 725, coupled in feedback to accumulator 720. Note that the digital filter can be of other topologies in other implementations. The digital value output from the digital filter is proportional to the PA output voltage (root mean squared (RMS)).

Based on the digital value output by level detector 710, a set of switches S30-S33 are controlled to provide, respectively, a bias voltage or a plus/minus reference voltage to the gate terminals of NMOS devices M32. As such, NMOS devices M32 operate to force the feedback current (Ifb) towards the value of the signal current (Is).

Thus envelope detector 700 is configured to generate a digital output signal that is proportional to the RF output signal (in terms of envelope amplitude square). In one implementation, the output of level detector 710 is a single-bit value (or can be multi-bit) that is provided to a digital filter. Since envelope detector 700 outputs a measured value that is already digitized, the envelope measurement can be done any point in time for as long is needed without constraints of sharing an ADC with other circuits.

In one implementation, envelope detector 700 receives the RF signal output from a dual-mode PA as Rfin=A(t)*cos(ωt+φ(t)), and generates a voltage measurement as Vdet_out=D=(A(t)/Vref/2)², where “D” is the density of “ones.”

In the embodiment of FIG. 7A, digital detector 700 is implemented as a voltage mode detector, as the gate voltages of NMOS devices M32 switch; however, due to RC time constant at these gate terminals, there may be relatively slow switching.

In another implementation, a digital envelope detector can be implemented as a current mode detector. Referring now to FIG. 7B, shown is a schematic diagram of a digital envelope detector in accordance with another embodiment. In general, detector 700′ may be implemented the same as detector 700 of FIG. 7A. However, note the differences in the switchable feedback that, in turn, couples to a set of switches S34-S37 that couple to drain terminals of MOSFETs M32_{A-C}. Thus, in this implementation, the drain currents generated by NMOS devices M32 are switching, enabling fast switching, since voltages are fixed, and further leading to reference and bias voltage impedance constraints to be more relaxed. In other aspects, detector 700′ may be implemented the same as detector 700.

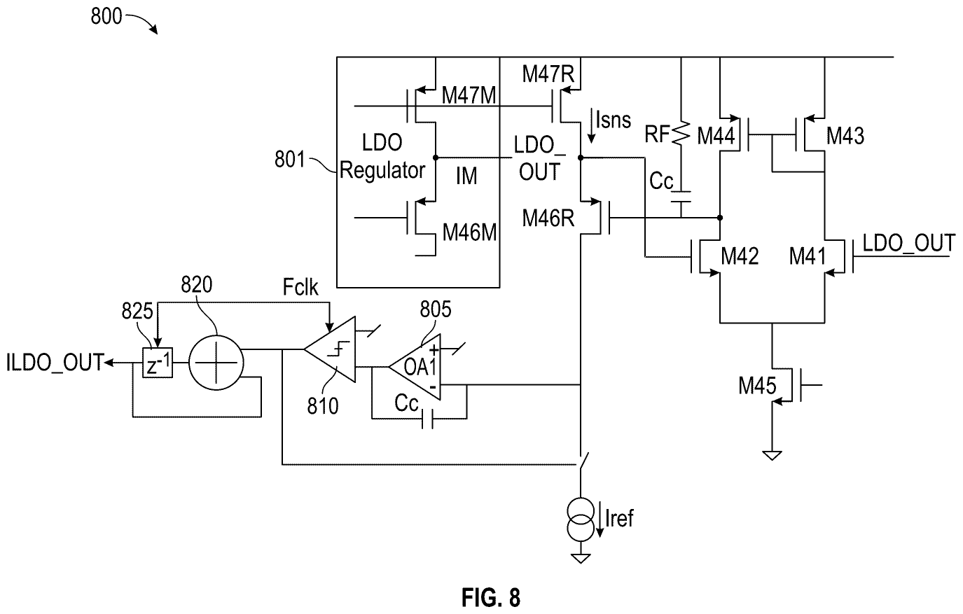

Referring now to FIG. 8, shown is a schematic diagram of a digital current detector in accordance with an embodiment. In the embodiment of FIG. 8, current detector 800 is configured to measure a current (LDO_OUT) output by an LDO 801 that provides a supply voltage to a dual-mode PA as described herein. This load current provides an understanding of load impedance. In this way, by sensing this current value, a controller can minimize gain or backoff operations, leading to operation of a dual-mode PA at or close to an optimal (efficiency-wise) power level.

As shown, the LDO current signal couples to a gate terminal of an NMOS device M41 commonly coupled with another NMOS device M42. These devices in turn couple to diode-connected PMOS device M43 and PMOS device M44. The commonly coupled drain terminals of MOSFETs M42, M44 couple to a gate terminal of replica circuitry that replicates output stage circuitry of LDO regulator 801. More specifically, this replica circuitry includes a PMOS device M46 having a drain terminal coupled to a second input of an op-amp 805, and a PMOS device M47R coupled via a drain terminal to a source terminal of PMOS device M46R and a gate terminal of NMOS device M42. These PMOS devices thus act as a replica circuit of corresponding circuitry of LDO regulator 801 (output stage circuitry shown as PMOS devices M47M and M46M, which generate a main current Im). Of course, the LDO PMOS devices are much larger than the replica PMOS devices. As such, the sensed current (Isns) is proportional to this main current.

As shown, current detector 800 includes op-amp 805, which compares this sensed current that is a measure of the LDO output current, received at the second input of op-amp 805 to a reference value. Op-amp 805 compares the signals and provides an output to a level detector 810, which provides a digital value to a digital filter formed of an accumulator 820 and a delay element 825, coupled in feedback to accumulator 820. Thus similar digital circuitry is present in current detector 800 as in voltage detector 700.

Here however, current detector 800 is configured to generate a digital output signal that is proportional to the LDO current, in turn dependent on a load impedance. In one implementation, the output of level detector 810 is a single-bit value (or can be multi-bit) that is provided to a digital filter. Since current detector 800 outputs a measured value that is already digitized, this current measurement can be done any point in time for as long is needed without constraints of sharing an ADC with other circuits.

During production testing, the digital detectors can be characterized to obtain characterization results, which can be stored in a non-volatile storage (such as flash or fuse circuitry) and then used during field operation. In one implementation, a two-step process may be used for each detector, based at least in part on a known PA load impedance, and a given output power level for the dual-mode PA. In an embodiment, current detector calibration is a two-point calibration, by changing the LDO current consumption (changing the PA slices or bias current). The two points allow calibration of offset and gain error. In an embodiment, the envelope detector calibration is a four-point calibration, applying two DC differential voltages across NMOS devices M31a/b (in FIG. 7A) with two different polarities. The measured four outputs are used to compensate for offset and gain error.

From this characterization, calibration data, e.g., voltage and current measures respectively, can be determined and stored. More specifically, this calibration data may be stored in a non-volatile memory (e.g., flash or fuses) of the transceiver. In an embodiment, the calibration data may include, for a given fixed impedance and output power level, a load current value (referred to further herein as ildopte) and an output voltage value (referred to further herein as Vdrainpte).

During field operation, PA gain can be measured during a preamble portion of a communication. In an embodiment, during the preamble a PA drain voltage swing (Vdrainpreamble) and a sensed LDO current (ildopreamble) can be measured using the digital detectors. Based on these measurements and the stored calibration values from production testing (Vdrainpte and ildopte), a gain swing (Gswing=Vdrainpreamble/Vdrainpte), and a current difference (Δildo=ildopte-ildopreamble) can be measured. Next a load gain can be calculated as follows, in one embodiment: Gload=Δildo/k (where k is an empirically determined constant, e.g., 1.5 mA, which can be a digitally programmable value). In turn, a gain correction can be determined as follows: Gcorrection=Gswing*Gload. This gain correction may be applied to the PA, e.g., on a next packet. Depending on implementation, such gain correction may be performed by controlling a number of slices of the dual-mode PA to be enabled, controlling digital I/Q values provided to the transmit signal path, an/or adjusting output impedance via an impedance transformation circuit as described herein.

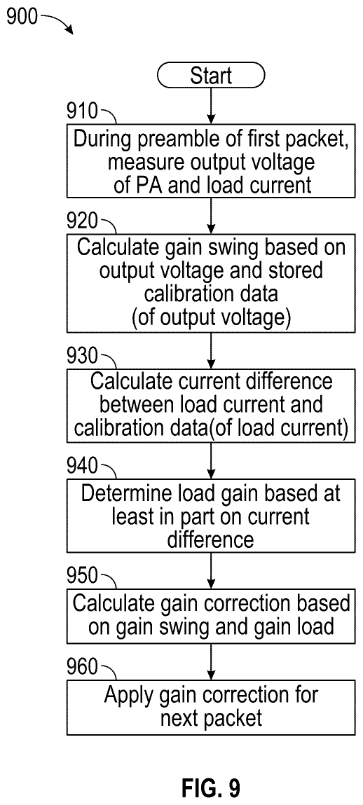

Referring to FIG. 9, shown is a flow diagram of a method in accordance with an embodiment. As shown in FIG. 9, method 900 is a method for dynamically calibrating a gain of a dual-mode PA. In one or more embodiments, method 900 can be performed by a controller of a wireless device, which may perform instructions of firmware and/or software stored in a non-volatile memory of the wireless device.

As shown, method 900 begins by measuring an output voltage of the PA and a load current (block 910). In an embodiment, these measurements may be made using digital detectors as described herein, and may be performed during a preamble of a first packet. In one implementation, the output voltage may be measured based on a drain voltage of all active slices of the PA, and the load current may be measured based on an LDO current provided to the PA.

Next at block 920, a gain swing may be calculated. More specifically, this gain swing can be calculated based on the measured output voltage and stored calibration data. As discussed above, the stored calibration data, which may be obtained from a non-volatile memory of the device, includes a calibration output voltage. Then at block 930 a current difference between the measured load current and stored calibration data can be determined. As discussed, the stored calibration data includes a LDO current.

Still referring to FIG. 9, at block 940 a load gain can be determined. This load gain may be based at least in part on this current difference. Then at block 950, a gain correction can be calculated. In the embodiment of FIG. 9, this gain correction may be calculated based on the gain swing and the gain load. In a particular implementation, the gain correction may be a product of the gain swing and the gain load. Thus at this point a gain correction value is available.

Because of timing issues, the gain correction can be applied for a next packet of the communication (block 960). Depending on implementation and the level of gain correction, this gain compensation can be realized by adjusting a number of active slices of the PA, controlling a level of digital I/Q values provided to the transmit path, and/or adjusting an impedance level of an impedance transformer as described herein. Although shown at this high level in the embodiment of FIG. 9, many variations and alternatives are possible.

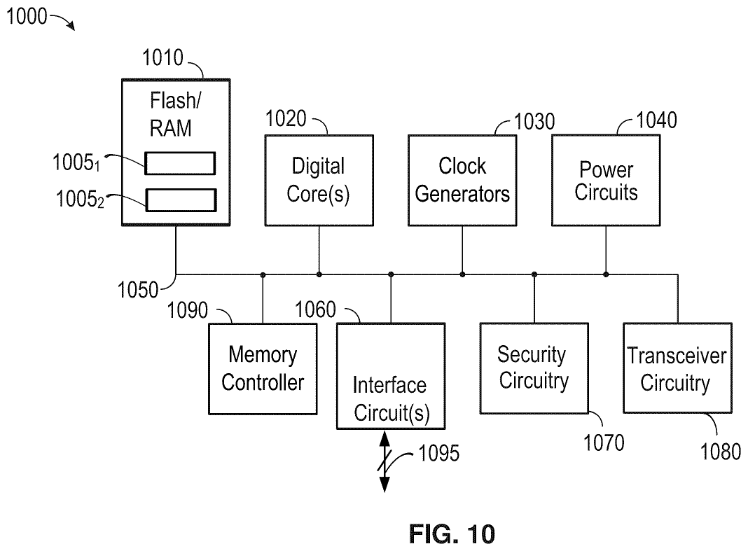

Referring now to FIG. 10, shown is a block diagram of a representative integrated circuit 1000 that includes a dual-mode PA as described herein. In the embodiment shown in FIG. 10, integrated circuit 1000 may be, e.g., a multi-mode wireless transceiver that may operate according to one or more wireless protocols (e.g., Wi-Fi, Bluetooth, BLE, IEEE 802.15.4, Matter and/or Zigbee, among others) or other device that can be used in a variety of use cases. In one or more embodiments, the circuitry of integrated circuit 1000 shown in FIG. 10 may be implemented on a single semiconductor die or implemented on separate dies for wireless communication, MCU compute, external flash and/or other IP blocks needed to perform a variety of functionalities.

Integrated circuit 1000 may be included in a range of devices, but for purposes of discussion, it may be incorporated into an IoT device. In the embodiment shown, integrated circuit 1000 includes a memory system 1010 which in an embodiment may include volatile storage, such as RAM and non-volatile memory such as a flash memory. The flash memory is a non-transitory storage medium that can store instructions and data. In embodiments, this storage may store calibration data 1005₁ (including but not limited to PA drain voltage and LDO current measurements made at a given power and load impedance level during production testing as described above) and a calibration routine 1005₂ to perform dynamic calibration in the field using calibration data 1005₁ and measurements from digital detectors as described above, which may execute on a main or host processor (implemented in at least one core of one or more digital cores 1020). Integrated circuit 1000 also may include a memory controller 1090.

Memory system 1010 couples via a bus 1050 to digital cores 1020, which may include one or more cores, co-processors, and/or microcontrollers that act as processing units of the integrated circuit as described herein. In turn, digital cores 1020 may couple to clock generators 1030 which may provide one or more phase locked loops or other clock generator circuitry to generate various clocks for use by circuitry of the IC.

As further illustrated, IC 1000 further includes power circuitry 1040. Additional circuitry may be present depending on particular implementation to provide various functionality and interaction with external devices. Such circuitry may include interface circuitry 1060 which provides a digital communication interface with additional circuitry that couples to IC 1000 via a link 1095. IC 1000 also may include security circuitry 1070 to perform wireless security techniques.

In addition, as shown in FIG. 10, transceiver circuitry 1080 may be provided to enable transmission and reception of wireless signals, e.g., according to one or more of a local area or wide area wireless communication scheme, such as Matter, Zigbee, Bluetooth Classic, BLE, IEEE 802.11, IEEE 802.15.4, cellular communication or so forth, using a dual-mode PA and impedance transformation circuitry, as described herein. Understand while shown with this high level view, many variations and alternatives are possible.

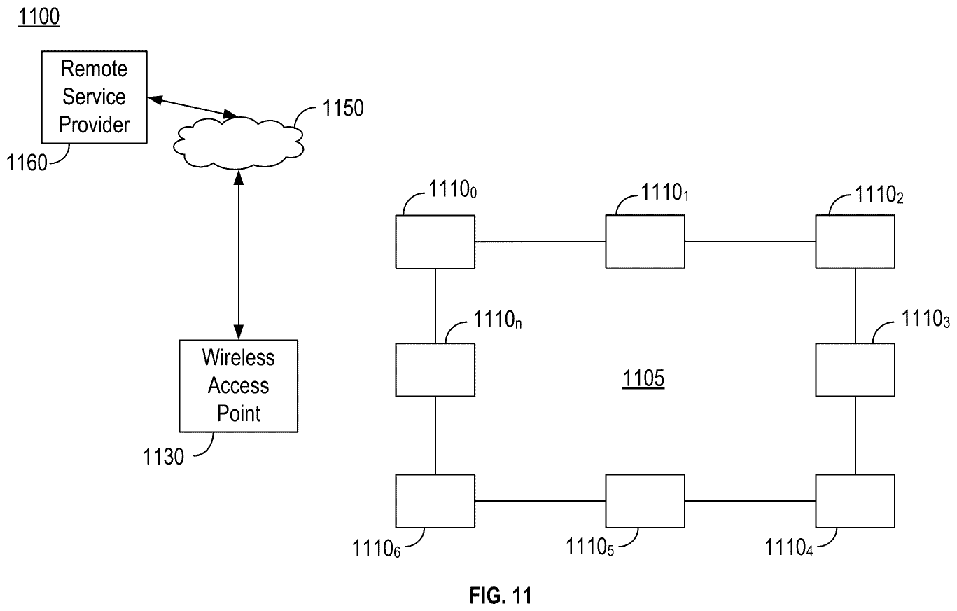

ICs such as described herein may be implemented in a variety of different devices as described above. Referring now to FIG. 11, shown is a high level diagram of a network in accordance with an embodiment. As shown in FIG. 11, a network 1100 includes a variety of devices, including IoT devices which may include dual-mode PAs as described herein, access points and remote service providers.

In the embodiment of FIG. 11, a wireless mesh network 1105 is present, e.g., in a building having multiple wireless devices 1110₀₋ₙ. As shown, wireless devices 1110, which may include IoT devices having dual-mode PAs, couple to an access point 1130 that in turn communicates with a remote service provider 1160 via a wide area network 1150, e.g., the Internet. Understand while shown at this high level in the embodiment of FIG. 11, many variations and alternatives are possible.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a dual-mode power amplifier to amplify a first radio frequency (RF) signal of a first wireless protocol according to a linear mode of operation, and to amplify a second RF signal of a second wireless protocol according to a non-linear mode of operation;
at least one digital feedback circuit coupled to the dual-mode power amplifier, the at least one digital feedback circuit to provide feedback information; and
a controller to control a power level of the dual-mode power amplifier based at least in part on the feedback information.

2. The apparatus of claim 1, wherein the at least one digital feedback circuit comprises an envelope detector comprising:
a comparator to compare a measure of the first RF signal to a reference value and output a digital value based on the comparison; and
a digital filter coupled to the comparator, the digital filter to output, based at least in part on the digital value, the feedback information comprising a root mean square value of the first RF signal.

3. The apparatus of claim 1, wherein the at least one digital feedback circuit comprises a current detector comprising:
a comparator to compare a first value representative of a current output by a voltage regulator coupled to the dual-mode power amplifier to a reference value and output a digital value based on the comparison; and
a digital filter coupled to the comparator, the digital filter to output, based at least in part on the digital value, the feedback information comprising the current output by the voltage regulator.

4. The apparatus of claim 1, wherein the controller is to determine a correction value for the dual-mode power amplifier, based at least in part on the feedback information obtained during a preamble portion of a first packet and at least one stored calibration value.

5. The apparatus of claim 4, wherein the controller is to:
calculate a gain swing based on a voltage value of the feedback information and a first calibration value from a non-volatile memory;
calculate a difference between a current value of the feedback information and a second calibration value from the non-volatile memory;
determine a load gain based at least in part on the difference; and
determine the correction value based on the gain swing and the load gain.

6. The apparatus of claim 4, wherein the controller is to apply the correction value for a second packet following the first packet.

7. The apparatus of claim 6, wherein the controller is to apply the correction value for the second packet via an update to a level of digital data of the second packet.

8. The apparatus of claim 1, wherein the dual-mode power amplifier comprises a plurality of slices, wherein a portion of the plurality of slices are to be re-used in the linear mode of operation and the non-linear mode of operation.

9. The apparatus of claim 8, wherein the controller, based at least in part on the feedback information, is to update a number of active slices of the plurality of slices.

10. A method comprising:
amplifying, in a power amplifier of a wireless device operating in a linear mode, a first radio frequency (RF) signal of a first wireless protocol;
amplifying, in the power amplifier operating in a non-linear mode, a second RF signal of a second wireless protocol; and
controlling a programmable impedance circuit coupled to an output of the power amplifier based at least in part on a power level of the power amplifier.

11. The method of claim 10, further comprising:
during a preamble portion of a first packet, digitally measuring a voltage at the output of the power amplifier via a first digital detector; and
during the preamble portion of the first packet, digitally measuring a current output by a voltage regulator that supplies an operating voltage to the power amplifier via a second digital detector.

12. The method of claim 11, further comprising:
determining a gain calibration for the power amplifier based at least in part on the voltage, the current, and one or more calibration values stored in a non-volatile memory; and
applying the gain calibration to the power amplifier during a second packet.

13. The method of claim 12, wherein applying the gain calibration comprises updating a level of digital data of the second packet.

14. The method of claim 12, wherein applying the gain calibration comprises controlling the programmable impedance circuit.

15. The method of claim 12, wherein the power amplifier comprises a plurality of slices, and applying the gain calibration comprises updating a number of the plurality of slices to be enabled.

16. The method of claim 10, wherein the power amplifier comprises a plurality of slices, the method further comprising:
amplifying, in a first number of slices of the plurality of slices of the power amplifier operating in the non-linear mode, the second RF signal of the second wireless protocol; and
amplifying, in a second number of slices of the plurality of slices of the power amplifier operating in the linear mode, the first RF signal of the first wireless protocol, at least some of the first number of slices included in the second number of slices.

17. The method of claim 10, further comprising:
controlling the programmable impedance circuit to have a first impedance level when amplifying the first RF signal; and
controlling the programmable impedance circuit to have a second impedance level when amplifying the second RF signal.

18. A system comprising:
an antenna to transmit and receive radio frequency (RF) signals; and
a multi-protocol transceiver coupled to the antenna, the multi-protocol transceiver comprising:
a dual-mode power amplifier to amplify a first RF signal of a first wireless protocol according to a linear mode of operation, and to amplify a second RF signal of a second wireless protocol according to a non-linear mode of operation;
an impedance transformation circuit coupled to an output of the dual-mode power amplifier;
at least one digital feedback detector coupled to the dual-mode power amplifier, the at least one digital feedback detector to provide feedback information; and
a controller to control an impedance of the impedance transformation circuit based at least in part on the feedback information.

19. The system of claim 18, further comprising a non-volatile storage to store compensation data, the compensation data comprising a first compensation value associated with an output voltage of the dual-mode power amplifier and a second compensation value associated with a load current of the dual-mode power amplifier.

20. The system of claim 19, wherein the controller is to control the impedance of the impedance transformation circuit further based on at least one of the first compensation value or the second compensation value.
